(19) United States
(12) Patent Application Publication
(10) Pub. No.: US 2023/0246031 A1
(43) Pub. Date: Aug. 3, 2023

(54) THREE-DIMENSIONAL ASYMMETRICAL VERTICAL TRANSISTOR ARCHITECTURES

(71) Applicant: Tokyo Electron Limited, Tokyo (JP)

(72) Inventors: Mark I. GARDNER, Albany, NY (US); H. Jim FULFORD, Albany, NY (US)

(73) Assignee: Tokyo Electron Limited, Tokyo (JP)

(21) Appl. No.: 17/592,095

(22) Filed: Feb. 3, 2022

(51) Int. Cl. H01L 27/092; H01L 29/08; H01L 29/10; H01L 29/78; H01L 29/66; H01L 21/8238

(52) U.S. Cl. CPC H01L 27/0922; H01L 29/0847; H01L 29/1037; H01L 29/7827; H01L 29/66666; H01L 21/823807; H01L 21/823814; H01L 21/823885

(57) ABSTRACT

Aspects of the present disclosure provide a 3D semiconductor structure and a method for fabricating the same. The 3D semiconductor structure can include a vertical field-effect transistor (VFET). The VFET can include a lower source/drain (S/D) region, a channel formed on the lower S/D region, a gate region surrounding the channel, and an upper S/D region formed on the channel. One of the lower and upper S/D regions can include a channel material having a graded dopant profile. The VFET can further include lower and upper S/D electrodes coupled to the lower and upper S/D regions, respectively, a gate electrode coupled to the gate region, a lower S/D spacer formed between the lower S/D electrode and the gate electrode, and an upper S/D spacer formed between the gate electrode and the upper S/D electrode. The upper S/D spacer can have a different thickness from the lower S/D spacer.

### FIELD OF THE DISCLOSURE

The present disclosure relates to semiconductor fabrication, and, more particularly, to three-dimensional (3D) asymmetrical vertical transistor architectures and methods for fabricating the same.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

In the manufacture of a semiconductor device, for example especially on the micro- or nanoscale, various fabrication processes can be executed, such as film-forming depositions, etch mask creation, patterning, material etching and removal, and doping treatments. These processes can be performed repeatedly to form desired semiconductor device elements on a substrate. With microfabrication, transistors can have been created in one plane with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of one another.

### SUMMARY

3D integration, i.e., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (e.g., a central processing unit (CPU), a graphics processing unit (GPU), a field programmable gate array (FPGA) and a system on chip SoC)) is being pursued.

Aspects of the present disclosure provide a three-dimensional (3D) semiconductor structure. For example, the 3D semiconductor structure can include a first vertical field-effect transistor (VFET). The first VFET can include a first lower source/drain (S/D) region, a first channel formed on the first lower S/D region, a first gate region surrounding the first channel, and a first upper S/D region formed on the first channel. In an embodiment, one of the first lower and upper S/D regions can include a first channel material having a first graded dopant profile.

In an embodiment, the first VFET can further include a first lower S/D electrode coupled to the first lower S/D region, a first gate electrode coupled to the first gate region, a first lower S/D spacer formed between the first lower S/D electrode and the first gate electrode, a first upper S/D electrode coupled to the first upper S/D region, and a first upper S/D spacer formed between the first gate electrode and the first upper S/D electrode, the first upper S/D spacer having a different thickness from the first lower S/D spacer.

In an embodiment, the 3D semiconductor structure can further include a second VFET stacked over the first VFET. The second VFET can include a second lower S/D region formed over the first VFET, a second channel formed on the second lower S/D region, a second gate region surrounding the second channel, and a second upper S/D region formed on the second channel. For example, one of the second lower and upper S/D regions can include a second channel material having a second graded dopant profile. As another example, the first and second channels can include different types of channel materials.

In an embodiment, the first gate region can include a first gate material coupled to the first channel and a first metal material coupled to the first gate material.

Aspects of the present disclosure provide a 3D semiconductor structure. For example, the 3D semiconductor structure can include a first VFET. The first VFET can include a first S/D region, a first channel formed on the first lower S/D region, a first gate region surrounding the first channel, a first upper S/D region formed on the first channel, a first lower S/D electrode coupled to the first lower S/D region, a first gate electrode coupled to the first gate region, a first lower S/D spacer formed between the first lower S/D electrode and the first gate electrode, a first upper S/D electrode coupled to the first upper S/D region, and a first upper S/D spacer formed between the first gate electrode and the first upper S/D electrode. In an embodiment, the first upper S/D spacer can have a different thickness from the first lower S/D spacer. Moreover, one of the first lower and upper S/D regions can include a first channel material having a first graded dopant profile.

Aspects of the present disclosure provide a method for fabricating a 3D semiconductor structure. For example, the method can include forming a multilayer stack on a substrate and forming a first opening through the first multilayer stack until uncovering a top surface of the substrate. The method can further include forming in the first opening a first VFET that includes a first lower S/D region, a first channel formed on the first lower S/D region, and a first upper S/D region formed on the first channel, and forming a first gate region of the first VFET surrounding the first channel. In an embodiment, one of the first lower and upper S/D region includes a first channel material having a first graded dopant profile.

In an embodiment, the multilayer stack can include first lower and upper S/D layers coupled to the first lower and upper S/D regions, respectively, a first gate layer coupled to the first gate region, a second lower S/D layer formed between the first lower S/D layer and the first gate layer, and a second upper S/D layer formed between the first upper S/D layer and the first gate layer, the second upper S/D layer having a different thickness from the second lower S/D layer. For example, the first lower and upper S/D layers can include first and second metal layers, respectively. As another example, the first lower and upper S/D layers can include first lower and upper dielectric layers, respectively, and the method can further include replacing the first lower and upper dielectric layers with first lower and upper metal layers, respectively.

In an embodiment, the method can further include forming in the first opening a second VFET over the first VFET, the second VFET including a second lower S/D region formed over the first VFET, a second channel formed on the second lower S/D region, and a second upper S/D region formed on the second channel, and forming a second gate region of the second VFET surrounding the second channel. For example, one of the second lower and upper S/D regions includes a second channel material having a second graded dopant profile. As another example, the first and second channels include different types of channel materials.

In an embodiment, the first gate region can include a first gate material coupled to the first channel and a first metal material coupled to the first gate material. For example, the multilayer stack can include a dielectric layer coupled to the first channel, and the method can further include replacing the dielectric layer with the first gate material and the first metal material to form the first gate region.

In an embodiment, the first gate region can be formed in the first opening. In another embodiment, the method can further include forming a second opening through the multilayer stack until uncovering the top surface of the substrate, and forming in the second opening a second VFET. For example, the second opening can have a different size from the first opening.

Note that this summary section does not specify every embodiment and/or incrementally novel aspect of the present disclosure or claimed disclosure. Instead, this summary only provides a preliminary discussion of different embodiments and corresponding points of novelty. For additional details and/or possible perspectives of the disclosure and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIGS. 1-6 are cross-sectional views illustrating an exemplary method for fabricating a 3D semiconductor structure with symmetrical transistor spacers and asymmetrical source/drain (S/D) junction grading, according to some embodiments of the present disclosure;

FIG. 6A is a schematic view of the 3D semiconductor structure shown in FIG. 6;

FIGS. 7 and 8 are cross-sectional views illustrating an exemplary method for fabricating a 3D semiconductor structure with asymmetrical transistor spacers and asymmetrical S/D junction grading, according to some embodiments of the present disclosure;

FIG. 8A is a schematic view of the 3D semiconductor structure shown in FIG. 8;

FIGS. 9-14 are cross-sectional views illustrating an exemplary method for fabricating a 3D semiconductor structure with S/D electrodes first and gate electrode last with asymmetrical transistor spacers and asymmetrical S/D junction grading, according to some embodiments of the present disclosure;

FIG. 14A is a schematic view of the 3D semiconductor structure shown in FIG. 14;

FIGS. 15-20 are cross-sectional views illustrating an exemplary method for fabricating a 3D semiconductor structure integrating in the same vertical 3D stack a symmetrical S/D junction 3D transistor with a 3D transistor with asymmetrical transistor spacers and asymmetrical S/D junction grading, according to some embodiments of the present disclosure; and

FIGS. 21-28 are cross-sectional views illustrating an exemplary method for fabricating a 3D semiconductor structure S/D electrodes first and gate electrode last with asymmetrical transistor spacers and asymmetrical S/D junction grading, according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

Techniques herein can enable 3D stacks of PMOS and/or NMOS devices with an asymmetrical/symmetrical source/drain (S/D) doping gradient and asymmetrical/symmetrical offset spacers. Since the source of a transistor is grounded (low E field in the source region), the vertical offset S/D spacers and/or heavily doped region on this transistor side may have a reduce thickness, which produces more Idsat and better off state leakage for the same transistor geometry area. Techniques herein can enable a more compact design with higher performance.

Example embodiments will now be described with reference to the drawings. Process flows can describe methods for fabricating a 3D semiconductor structure with asymmetrical/symmetrical dopant profiles and asymmetrical/symmetrical offset spacers. For example, one of the source and drain regions of a transistor can have a graded dopant profile, and the other can have a constant dopant profile. As another example, the source and drain spacers can have different thicknesses.

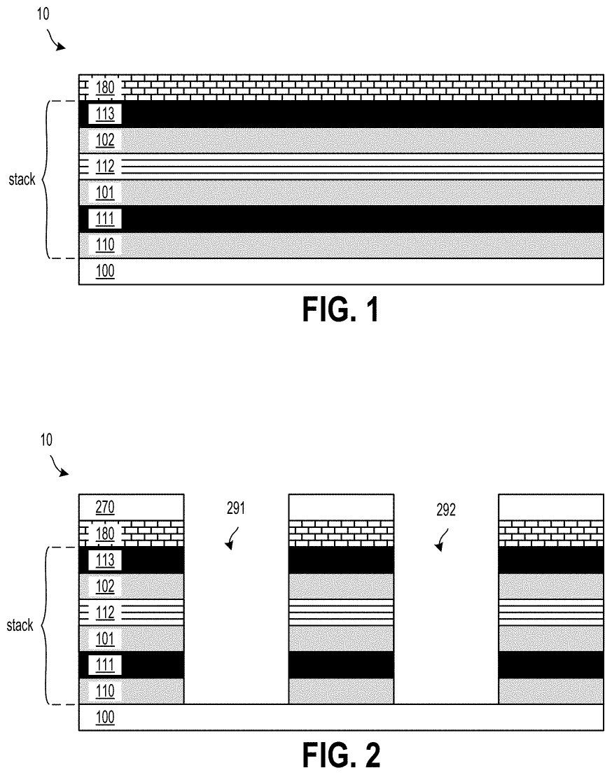

FIGS. 1-6 are cross-sectional views illustrating an exemplary method for fabricating a 3D semiconductor structure 10 with symmetrical transistor spacers and asymmetrical source/drain (S/D) junction grading, according to some embodiments of the present disclosure. As shown in FIG. 1, a substrate (e.g., a Si or SiGe substrate) 100 is provided, and a stack of dielectric and metal layers (or a multilayer stack) are formed (e.g., deposited) on the substrate 100. For example, the stack can include a bottom dielectric layer 110, a lower metal layer 111, a lower dielectric layer 101, a middle metal layer 112, an upper dielectric layer 102 and an upper metal layer 113 that are formed (e.g., deposited) on the substrate 100 sequentially. The lower and upper metal layers 111 and 113 can be used to form source/drains (S/Ds), e.g., S/D electrodes, of vertical field-effect transistors (VFETs), e.g., first and second (or left and right) VFETs. The middle metal layer 112 can be used to form gates, e.g., gate electrodes, of the first and second VFETs. The lower and upper dielectric layers 101 and 102 can be used to form S/D spacers between the S/Ds and gates of the first and second VFETs. The lower and upper dielectric layers 101 and 102 can have the same thickness, and the first and second VFETs have symmetrical transistor spacers. Since the spacers (i.e., the lower and upper dielectric layers 101 and 102) can be deposited and formed on the lower metal layer 111 and the middle metal layer 112, respectively, their thicknesses can be controlled to monolayer precision. A cap layer 180 can be formed over the stack.

As shown in FIG. 2, a photoresist (PR) mask 270 can be patterned by photolithography, for example, and formed to cover a portion of the cap layer 180 (and the stack), and the rest of the cap layer 180 (and the stack) that is not covered by the PR mask 270 can be etched downward until uncovering the top surface of the substrate 100 to form at least one opening, e.g., first and second openings 291 and 292. The first and second openings 291 and 292 allow the first and second VFETs to be formed therein, respectively.

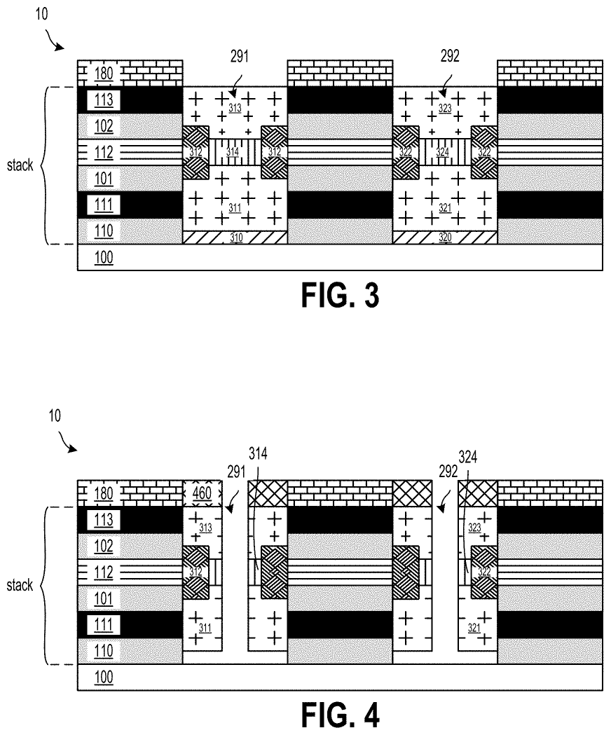

As shown in FIG. 3, the PR mask 270 (which is shown in FIG. 2) can be removed, and the first and second VFETs can be formed in the first and second openings 291 and 292, respectively.

For example, first and second (sacrificial) epitaxial material 310 and 320 can be formed (e.g., epitaxially grown) on the substrate 100 within the first and second openings 291 and 292, respectively. The first and second epitaxial materials 310 and 320 can be aligned with the bottom dielectric layer 110 or cover a portion of a vertical sidewall of the bottom dielectric layer 110. The first and second epitaxial materials 310 and 320 can be, for example, Si or SiGe, among others.

A first source region 311 of the first VFET and a second source region 321 of the second VFET can be formed (e.g., epitaxially grown) on the first and second epitaxial materials 310 and 320, respectively, with a lower channel material, e.g., a P type or N type epitaxial material. The lower channel material can have a high dopant profile. The first and second source regions 311 and 321 can cover a vertical sidewall of the lower metal layer 111 of the stack or further cover a portion of the vertical sidewall of the bottom dielectric layer 110 and/or a portion of a vertical sidewall of the lower dielectric layer 101, which is between the lower metal layer 111 and the middle metal layer 112.

A first gate region 312 of the first VFET can be formed (e.g., deposited) on the first source region 311 with a first gate material, e.g., a first high-k material, and a second gate region 322 of the second VFET can be formed (e.g., deposited) on the second source region 321 with a second gate material, e.g., a second high-k material, which can be the same as or different from the first gate material. In an embodiment, the first and second gate regions 312 and 322 can cover the vertical sidewall of the middle metal layer 112 or further cover a portion of the vertical sidewall of the lower dielectric layer 101 and/or a portion of a vertical sidewall of the upper dielectric layer 102.

First and second epitaxial channels 314 and 324 can be formed on the first and second source regions 311 and 321, respectively.

A first drain region 313 of the first VFET and a second drain region 323 of the second VFET can be formed (e.g., epitaxially grown) on the first and second epitaxial channels 314 and 324, respectively, with a higher channel material, e.g., a P type or N type epitaxial material. The higher channel material can have a graded dopant profile. Accordingly, the first and second source regions 311 and 321 and the first and second drain regions 313 and 323 have asymmetrical dopant profiles. The first and second drain regions 313 and 323 can cover a vertical sidewall of the upper metal layer 113 of the stack or further cover a portion of the vertical sidewall of the upper dielectric layer 102.

As shown in FIG. 4, a dielectric layer 460 can be formed to cover a portion of the first and second drain regions 313 and 323, and the rest of the first and second drain regions 313 and 323 that is not covered by the dielectric layer 460 can be etched downward until uncovering the top surface of the substrate 100. The first and second epitaxial materials 310 and 320 can then be removed.

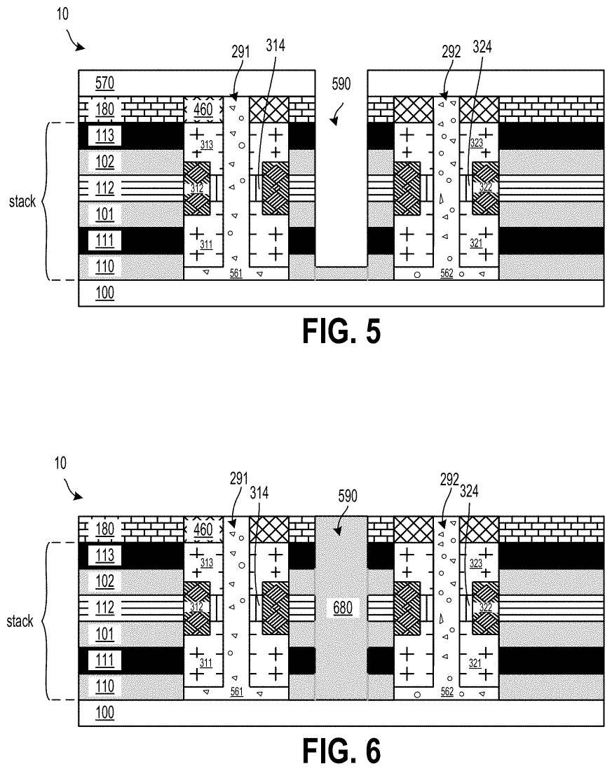

As shown in FIG. 5, first and second dielectric materials 561 and 562 can be deposited to replace the removed first and second epitaxial materials 310 and 320 (which are shown in FIG. 4) and fill the first and second openings 291 and 292, respectively, and planarized using CMP, for example, to be aligned with the cap layer 180 and the dielectric layer 460. A PR mask 570 can be patterned by photolithography, for example, and formed to cover a portion of the cap layer 180 over the entire first and second VFETs, and the rest of the cap layer 180 that is not covered by the PR mask 570 can be etched downward until uncovering at least the top surface of the bottom dielectric layer 110, to form an opening 590.

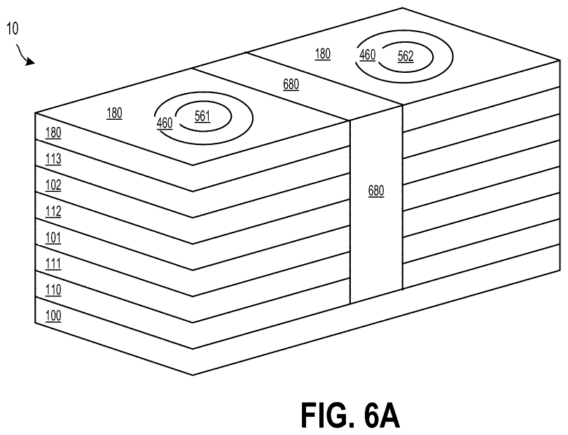

As shown in FIG. 6, the PR mask 570 (which is shown in FIG. 5) can be removed, and a dielectric material 680 can be deposited on the bottom dielectric layer 110 within the opening 590 and planarized using CMP, for example, to be aligned with the cap layer 180 and the dielectric layer 460

Accordingly, the semiconductor structure 10 can be formed to include the first and second VFETs, each of which has asymmetrical S/D dopant profiles (S/D junction grading) and symmetrical S/D spacers. The abrupt epi growth doping profile on the source regions (i.e., the first and second source regions 311 and 321) and the graded dopant profile on the drain regions (i.e., the first and second drain regions 313 and 323) provide a significant enhancement to the device Idsat and improved reliability properties. Many circuit elements, such as inverters, SRAMs, logic circuits, and other memory cells, have preferred direction for the transistor or device element current flow that the present disclosure can provide enhancement. FIG. 6A is a schematic view of the semiconductor structure 10 according to some embodiments of the present disclosure.

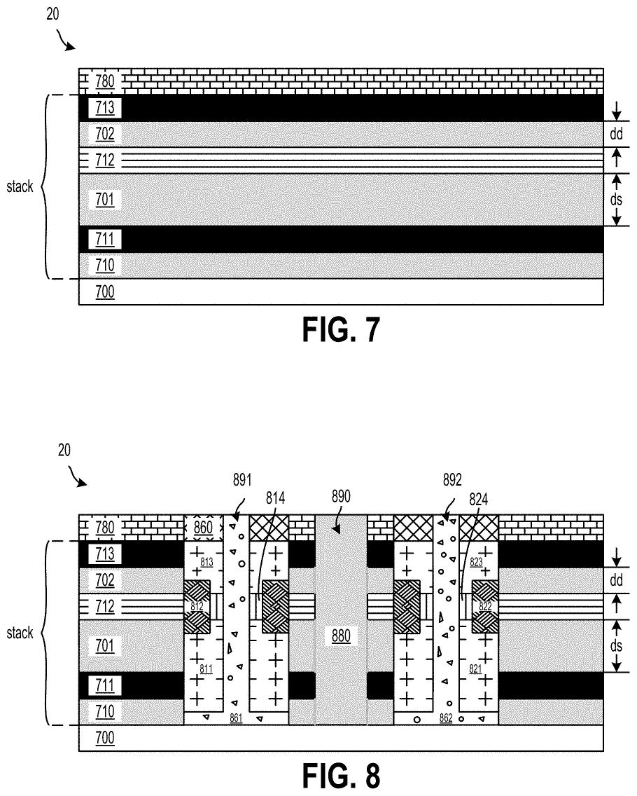

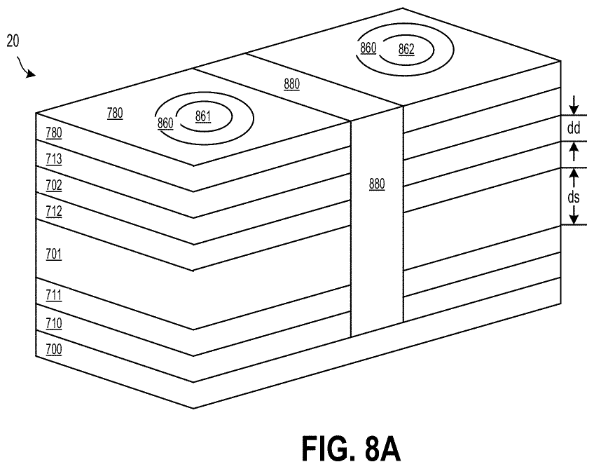

FIGS. 7 and 8 are cross-sectional views illustrating an exemplary method for fabricating a 3D semiconductor structure 20 with asymmetrical transistor spacers and asymmetrical source/drain (S/D) junction grading, according to some embodiments of the present disclosure. As shown in FIG. 7, a substrate (e.g., a Si or SiGe substrate) 700 is provided, and a stack of dielectric and metal layers (or a multilayer stack) are formed (e.g., deposited) on the substrate 700. For example, the stack can include a bottom dielectric layer 710, a lower metal layer 711, a lower dielectric layer 701, a middle metal layer 712, an upper dielectric layer 702 and an upper metal layer 713 that are formed (e.g., deposited) on the substrate 700 sequentially. The lower and upper metal layers 711 and 713 can be used to form sources/drains (S/Ds), e.g., S/D electrodes, of VFETs, e.g., first and second (or left and right) VFETs. The middle metal layer 712 can be used to form gates, e.g., gate electrodes, of the first and second VFETs. The lower and upper dielectric layers 701 and 702 can be used to form S/D spacers between the S/Ds and gates of the first and second VFETs. FIG. 7 differs from FIG. 1 in that in FIG. 7 the lower and upper dielectric layers 701 and 702 can have different thicknesses, e.g., a source spacer thickness ds and a drain spacer thickness dd. A cap layer 780 can be formed over the stack.

As shown in FIG. 8, the first and second VEFTs with different S/D spacer thicknesses can be formed, by following the processes shown in FIGS. 2-6. For example, a PR mask (not shown) can be patterned by photolithography, for example, and formed to cover a portion of the cap layer 780 (and the stack), and the rest of the cap layer 780 (and the stack) that is not covered by the PR mask can be etched downward until uncovering the top surface of the substrate 700 to form at least one opening, e.g., first and second openings 891 and 892, which allow the first and second VFETs to be formed therein, respectively; the PR mask can be removed; first and second (sacrificial) epitaxial material (not shown) can be formed (e.g., epitaxially grown) on the substrate 700 within the first and second openings 891 and 892, respectively; a first source region 811 of the first VFET and a second source region 821 of the second VFET can be formed (e.g., epitaxially grown) on the first and second epitaxial materials, respectively, with a lower channel material, e.g., a P type or N type epitaxial material, which can have a high dopant profile; a first gate region 812 of the first VFET can be formed (e.g., deposited) on the first source region 811 with a first gate material, e.g., a first high-k material, and a second gate region 822 of the second VFET can be formed (e.g., deposited) on the second source region 821 with a second gate material, e.g., a second high-k material, which can be the same as or different from the first gate material; the P type (or N type) epitaxial material growth can be continued from the first and second source regions 811 and 821 until being aligned with the middle metal layer 712 to form first and second epitaxial channels 814 and 824, respectively; a first drain region 813 of the first VFET and a second drain region 823 of the second VFET can be formed (e.g., epitaxially grown) on the first and second epitaxial channels 814 and 824, respectively, with a higher channel material (e.g., a P type or N type epitaxial material), which can have a graded dopant profile; a dielectric layer 860 can be formed to cover a portion of the first and second drain regions 813 and 823, and the rest of the first and second drain regions 813 and 823 can be etched downward until uncovering the top surface of the substrate 700; the first and second epitaxial materials can then be removed; first and second dielectric materials 861 and 862 can be deposited to replace the removed portions of the first and second epitaxial materials and fill the first and second openings 891 and 892, respectively, and planarized using CMP, for example, to be aligned with the cap layer 780 and the dielectric layer 860; another PR mask (not shown) can be patterned and formed to cover a portion of the cap layer 780 over the entire first and second VFETs, and the rest of the cap layer 780 that is not covered by the another PR mask can be etched downward until uncovering at least the top surface of the bottom dielectric layer 710, to form an opening 890; the another PR mask can be removed; and a dielectric material 880 can be deposited on the bottom dielectric layer 710 within the opening 890 and planarized using CMP, for example, to be aligned with the cap layer 780 and the dielectric layer 860.

Accordingly, the semiconductor structure 20 can be formed to include the first and second VFETs, each of which has asymmetrical S/D dopant profiles and asymmetrical S/D spacers. Therefore, the semiconductor structure 20 can be used as higher voltage (HV) devices, which require higher gate electrode voltage and drain voltage. FIG. 8A is a schematic view of the semiconductor structure 20 according to some embodiments of the present disclosure.

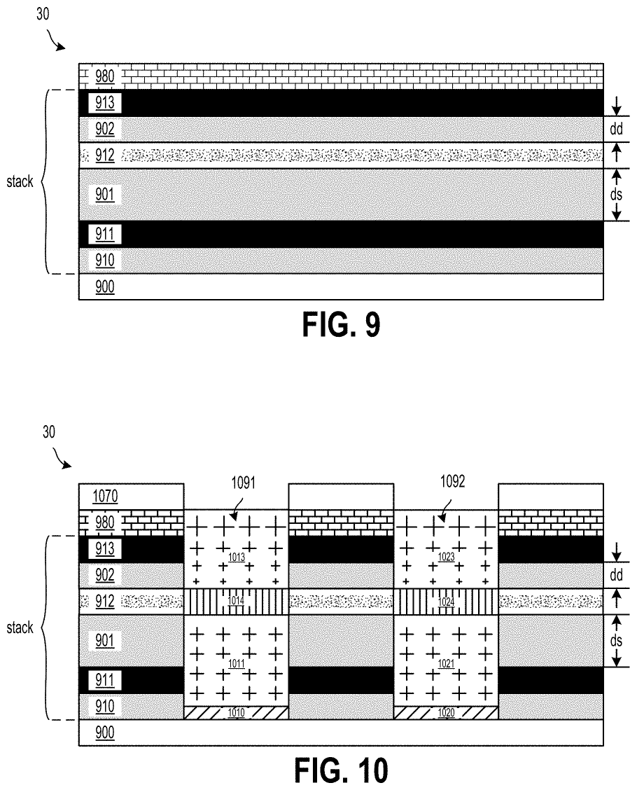

FIGS. 9-14 are cross-sectional views illustrating an exemplary method for fabricating a 3D semiconductor structure 30 with S/D electrodes first and gate electrode last with asymmetrical transistor spacers and asymmetrical source/drain (S/D) junction grading, according to some embodiments of the present disclosure. As shown in FIG. 9, a substrate (e.g., a Si or SiGe substrate) 900 is provided, and a stack of dielectric and metal layers (or a multilayer stack) are formed (e.g., deposited) on the substrate 900. For example, the stack can include a bottom dielectric layer 910, a lower metal layer 911, a lower dielectric layer 901, a middle dielectric layer 912, an upper dielectric layer 902 and an upper metal layer 913 that are formed (e.g., deposited) on the substrate 900 sequentially. The lower and upper metal layers 911 and 913 can be used to form sources/drains (S/Ds), e.g., S/D electrodes, of vertical field-effect transistors (VFETs), e.g., first and second (or left and right) VFETs. The lower and upper dielectric layers 901 and 902 can have different thicknesses, e.g., a source spacer thickness ds and a drain spacer thickness dd, as shown in FIG. 9, or have the same thickness. FIG. 9 differs from FIG. 7 in that in FIG. 9 the middle dielectric layer 912 replaces the middle metal layer 712 in FIG. 7. The middle dielectric layer 912 can be used to form gates, e.g., gate electrodes, of the first and second VFETs. Accordingly, the S/D electrodes can be formed first and the gate electrode can be formed last. A cap layer 980 can be formed over the stack.

As shown in FIG. 10, a PR mask 1070 can be patterned by photolithography, for example, and formed to cover a portion of the cap layer 980 (and the stack), and the rest of the cap layer 980 (and the stack) that is not covered by the PR mask 1070 can be etched downward until uncovering the top surface of the substrate 1000 to form at least one opening, e.g., first and second openings 1091 and 1092. The first and second openings 1091 and 1092 allow the first and second VFETs to be formed therein, respectively. The PR mask 1070 can then be removed.

Also shown in FIG. 10, first and second (sacrificial) epitaxial material 1010 and 1020 can be formed (e.g., epitaxially grown) on the substrate 1000 within the first and second openings 1091 and 1092, respectively. The first and second epitaxial materials 1010 and 1020 can be aligned with the bottom dielectric layer 910 or cover a portion of a vertical sidewall of the bottom dielectric layer 910. The first and second epitaxial materials 1010 and 1020 can be, for example, Si or SiGe, among others. A first source region 1011 of the first VFET and a second source region 1021 of the second VFET can be formed (e.g., epitaxially grown) on the first and second epitaxial materials 1010 and 1020, respectively, with a lower channel material, e.g., a P type or N type epitaxial material, until being aligned with the lower dielectric layer 901. First and second epitaxial channels 1014 and 1024 can be formed on the first and second source regions 1011 and 1021, respectively, until being aligned with the middle dielectric layer 912. A first drain region 1013 of the first VFET and a second drain region 1023 of the second VFET can be formed (e.g., epitaxially grown) on the first and second epitaxial channels 1014 and 1024, respectively, with a higher channel material, e.g., a P type or N type epitaxial material, until being aligned with the upper metal layer 913 or the cap layer 980. The higher channel material can have a graded dopant profile. Accordingly, the first and second source regions 1011 and 1021 and the first and second drain regions 1013 and 1023 have asymmetrical dopant profiles.

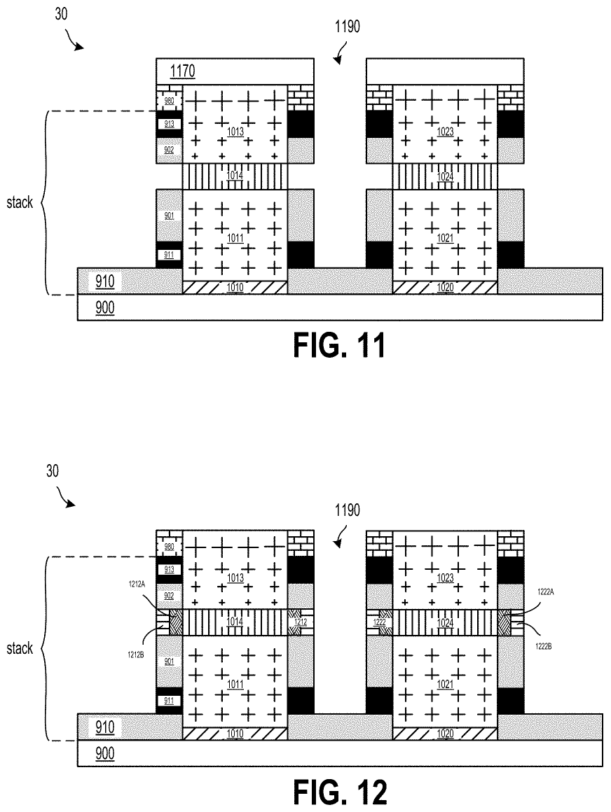

As shown in FIG. 11, a PR mask 1170 can be patterned by photolithography, for example, and formed to cover a portion of the cap layer 980 over the entire first and second VFETs, and the rest of the cap layer 980 that is not covered by the PR mask 1170 can be etched downward until uncovering the top surface of the bottom dielectric layer 910 (as shown in FIG. 12) or until uncovering the top surface of the substrate 900, to form an opening 1190. The PR mask 1170 can then be removed. The middle dielectric layer 912 (which is shown in FIG. 10), which is etched selectively with respect to the lower and upper dielectric layers 901 and 902 and the bottom dielectric layer 910, can be etched and removed.

As shown in FIG. 12, the removed middle dielectric layer 912 (which is shown in FIG. 10) surrounding the first VFET can be replaced with a first gate material 1212A and a first metal material 1212B (e.g., a first gate electrode) to form a first gate region 1212 of the first VFET, and the removed middle dielectric layer 912 surrounding the second VFET can be replaced with a second gate material 1222A and a second metal material 1222B (e.g., a second gate electrode) to form a second gate region 1222 of the second VFET. In an embodiment, the first gate material 1212A can include a first high-k material, and the second gate material 1222A can include a second high-k material that can be the same as or different from the first high-k material. In another embodiment, at least one of the first and second metal materials 1212B and 1222B can include two or more dielectric layered metal. The excess first and second metal materials 1212B and 1222B can be etched such that the first and second metal materials 1212B and 1222B can be aligned with the edge of the cap layer 980.

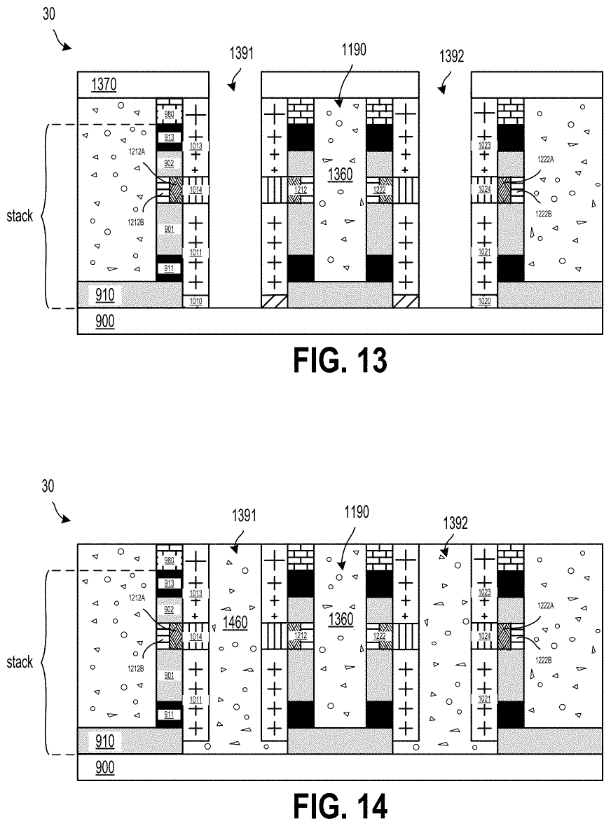

As shown in FIG. 13, a dielectric material 1360 can be deposited to fill the opening 1190 and planarized using CMP, for example, to be aligned with the cap layer 980. A PR mask 1370 can be patterned by photolithography, for example, and formed to cover a portion of the cap layer 980 (and the stack), and the rest of the cap layer 980 (and the stack) that is not covered by the PR mask 1370 can be etched downward until uncovering the top surface of the substrate 900 to form first and second openings 1391 and 1392.

As shown in FIG. 14, the PR mask 1370 (which is shown in FIG. 13) can be removed, and the first and second epitaxial materials 1010 and 1020 (which is shown in FIG. 13) can then be removed. A dielectric material 1460 can be deposited to fill the first and second openings 1391 and 1392 and planarized using CMP, for example, to be aligned with the cap layer 980.

Accordingly, the semiconductor structure 30 can be formed to include the first and second VFETs, each of which has asymmetrical S/D dopant profiles and asymmetrical S/D spacers. FIG. 14A is a schematic view of the semiconductor structure 30 according to some embodiments of the present disclosure.

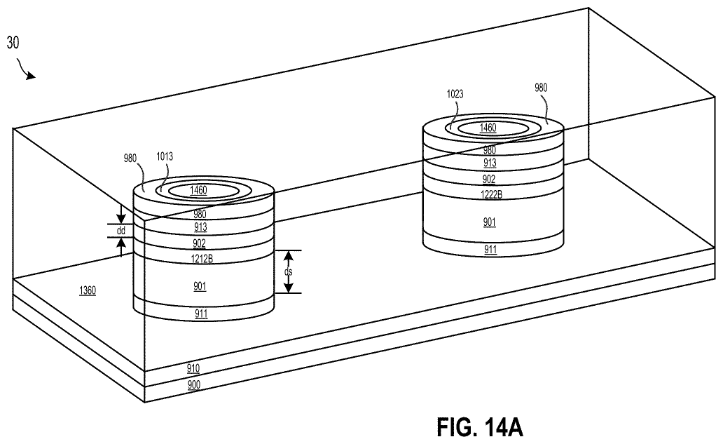

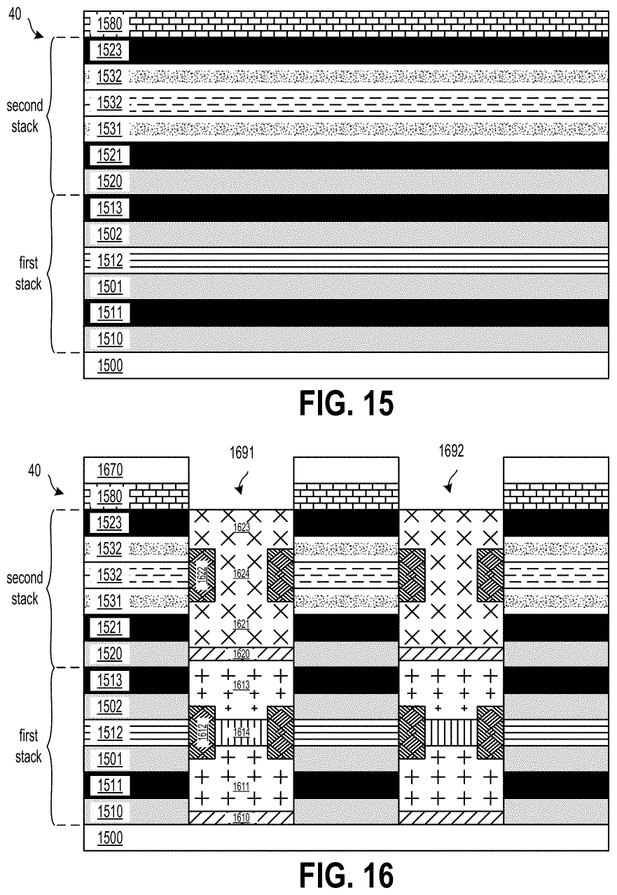

FIGS. 15-20 are cross-sectional views illustrating an exemplary method for fabricating a 3D semiconductor structure 40 integrating in the same vertical 3D stack a symmetrical S/D junction 3D transistor with a 3D transistor with asymmetrical transistor spacers and asymmetrical S/D junction grading, according to some embodiments of the present disclosure. As shown in FIG. 15, a substrate (e.g., a Si or SiGe substrate) 1500 is provided, and at least two stacks (e.g., a first stack and a second stack that is stacked on the first stack vertically) of dielectric and metal layers (or a first multilayer stack and a second multilayer stack that is stacked on the first multilayer stack vertically) are formed (e.g., deposited) on the substrate 1500. For example, the first stack can include a first bottom dielectric layer 1510, a first lower metal layer 1511, a first lower dielectric layer 1501, a first middle metal layer 1512, a first upper dielectric layer 1502 and a first upper metal layer 1513 that are formed (e.g., deposited) on the substrate 1500 sequentially, and the second stack can include a second bottom dielectric layer 1520, a second lower metal layer 1521, a second lower dielectric layer 1531, a second middle metal layer 1522, a second upper dielectric layer 1532 and a second upper metal layer 1523 that are formed (e.g., deposited) on the first upper metal layer 1513 of the first stack sequentially. The first lower and upper metal layers 1511 and 1513 can be used to form source/drains (S/Ds), e.g., S/D electrodes, of VFETs, e.g., left and right first VFETs. The first middle metal layer 1512 can be used to form gates, e.g., gate electrodes, of the left and right first VFETs. The first lower and upper dielectric layers 1501 and 1502 can have the same thickness, as shown in FIG. 15, or have different thicknesses. The second lower and upper metal layers 1521 and 1523 can be used to form source/drains (S/Ds), e.g., S/D electrodes, of VFETs, e.g., left and right second VFETs, which can be stacked over the left and right first VFETs, respectively. The second middle metal layer 1522 can be used to form gates, e.g., gate electrodes, of the left and right second VFETs. The second lower and upper dielectric layers 1531 and 1532 can have the same thickness, as shown in FIG. 15, or have different thicknesses. A cap layer 1580 can be formed on the second upper metal layer 1523 of the second stack.

As shown in FIG. 16, a PR mask 1670 can be patterned by photolithography, for example, and formed to cover a portion of the cap layer 1580, and the rest of the cap layer 1580 that is not covered by the PR mask 1670 can be etched downward until uncovering the top surface of the substrate 1500, to form at least one opening, e.g., left and right openings 1691 and 1692. The PR mask 1670 can then be removed. The left and right openings 1691 and 1692 allow the left first and second VFETs and the right first and second VFETs to be formed therein, respectively, sequentially.

For example, a first (sacrificial) epitaxial material 1610 can be formed (e.g., epitaxially grown) on the substrate 1500 within the left opening 1691. A first source region 1611 of the left first VFET can be formed (e.g., epitaxially grown) on the first epitaxial material 1610, with a lower channel material, e.g., a P type or N type epitaxial material. The lower channel material can have a high dopant profile. A first gate region 1612 of the left first VFET can be formed (e.g., deposited) on the first source region 1611 with a first gate material, e.g., a first high-k material. An epitaxial channel (or a first channel) 1614 can be formed on the first source region 1611. A first drain region 1613 of the left first VFET can be formed (e.g., epitaxially grown) on the epitaxial channels 1614, with a higher channel material, e.g., a P type or N type epitaxial material. The higher channel material can have a graded dopant profile. Accordingly, the first source region 1611 and the first drain region 1613 of the left first VFET have asymmetrical dopant profiles.

Then, a second epitaxial (sacrificial) material 1620 can be formed (e.g., epitaxially grown) on the first drain region 1613 of the left first VFET; a second source region 1621 of the left second VFET can be formed (e.g., epitaxially grown) on the second epitaxial material 1620 with the second type channel material, e.g., the N type epitaxial material (or with the first type channel material, e.g., the P type epitaxial material); a second gate region 1622 of the left second VFET can be formed (e.g., deposited) on the second source region 1621 with a second gate material, e.g., a second high-k material, which can be the same as or different from the first high-k material; the N type epitaxial material growth can be continued until being aligned with the second upper metal layer 1523 to form a second channel 1624 and a second drain region 1623 of the left second VFET. Accordingly, the left second VFET, which is with symmetrical transistor spacers and symmetrical S/D junction grading, is stacked on integrated with the left first VFET, which is with symmetrical transistor spacers and asymmetrical S/D junction grading, to form a left vertical complementary field-effect transistor (CFET) in the left opening 1691. The right first and second VFETs can also be formed in the right opening 1692 similarly. Accordingly, the right second VFET can be stacked on the right VFET to form a right vertical CFET in the right opening 1692.

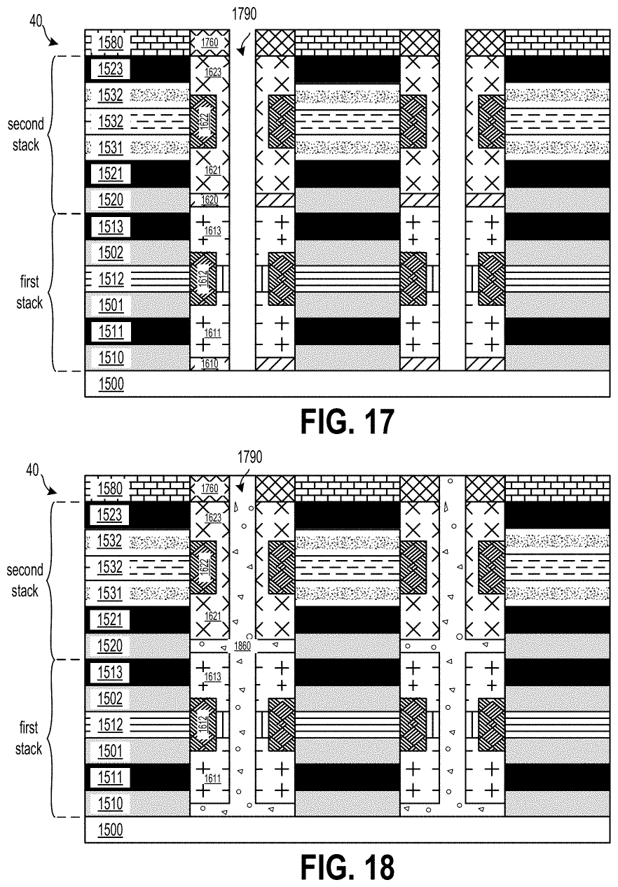

As shown in FIG. 17, a dielectric layer 1760 can be deposited to cover a portion of the left and right vertical CFETs, and the rest of the left and right vertical CFETs that is not covered by the dielectric layer 1760 can be etched downward until uncovering the top surface of the substrate 100, to form an opening 1790.

As shown in FIG. 18, the first and second epitaxial materials 1610 and 1620 (which are shown in FIG. 17) can be removed, and a dielectric material 1860 can be deposited to fill the opening 1790 and planarized using CMP, for example, to be aligned with the cap layer 1580.

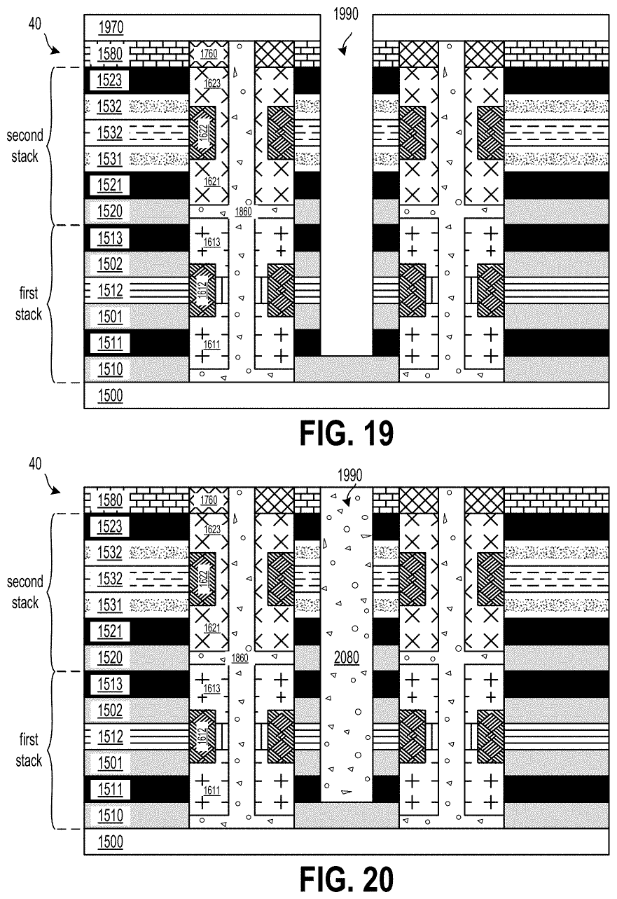

As shown in FIG. 19, a PR mask 1970 can be patterned by photolithography, for example, and formed to cover the entire dielectric layer 1760 and dielectric material 1860 and a portion of the cap layer 1580, and the rest of the cap layer 1580 that is not covered by the PR mask 1970 can be etched downward until uncovering at least the top surface of the first bottom dielectric layer 1510, to form an opening 1990.

As shown in FIG. 20, the PR mask 1970 (which is shown in FIG. 19) can be removed, and a dielectric material 2080 can be deposited to fill the opening 1990 and planarized using CMP, for example, to be aligned with the cap layer 1580.

Accordingly, the semiconductor structure 40 can be formed to include the left and right vertical CFETs each including vertically stacked first and second VFETs, one of which has asymmetrical S/D dopant profiles. In another embodiment, both of the first and second VFETs can have asymmetrical S/D dopant profiles. As shown in FIGS. 15-20, the first and second VEFTs of each of the left and right vertical CFETs have symmetrical S/D spacers. In another embodiment, the first lower and upper dielectric layers 1501 and 1502 and/or the second lower and upper dielectric layers 1531 and 1532 can have different thicknesses, and the first and/or second VFETs of each of the left and right vertical CFETs can have asymmetrical S/D spacers.

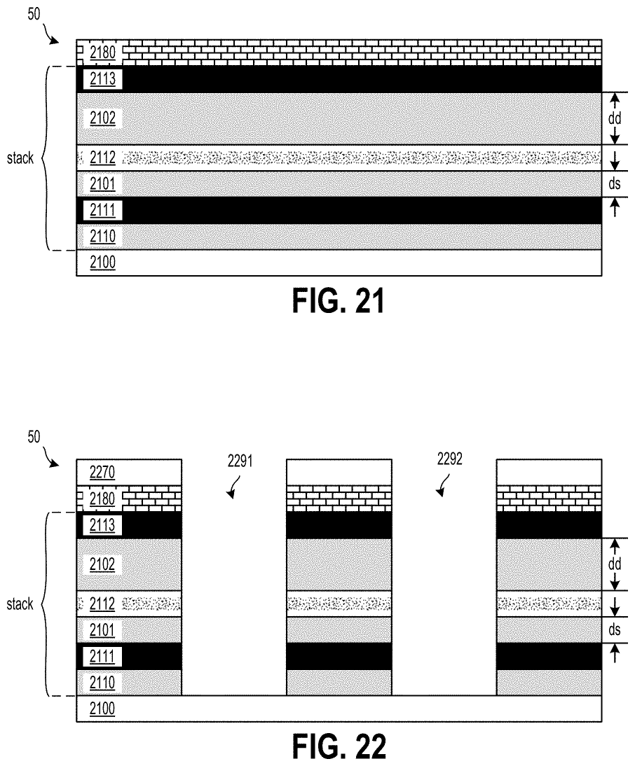

FIGS. 21-28 are cross-sectional views illustrating an exemplary method for fabricating a 3D semiconductor structure 50 with S/D electrodes first and gate electrode last with asymmetrical transistor spacers and asymmetrical S/D junction grading, according to some embodiments of the present disclosure. As shown in FIG. 21, a substrate (e.g., a Si or SiGe substrate) 2100 is provided, and a stack of dielectric layers (or a multilayer stack) are formed (e.g., deposited) on the substrate 2100. The stack shown in FIG. 21 differs from the stacks shown in FIGS. 1 and 7 at least in that in FIG. 21 the stack includes dielectric layers only. For example, the stack can include a bottom dielectric layer 2110, a first lower dielectric layer 2111, a second lower dielectric layer 2101, a middle dielectric layer 2112, a second upper dielectric layer 2102 and a first upper dielectric layer 2113 that are formed (e.g., deposited) on the substrate 2100 sequentially. The first lower and upper dielectric layers 2111 and 2113 can be used to form sources/drains (S/Ds), S/D electrodes, of vertical field-effect transistors (VFETs), e.g., first and second (or left and right) VFETs. The middle dielectric layer 2112 can be used to form gates, e.g., gate electrodes, of the first and second VFETs. The second lower and upper dielectric layers 2101 and 2102 can have different thicknesses, e.g., a source spacer thickness ds and a drain spacer thickness dd, as shown in FIG. 21, or have the same thickness. A cap layer 2180 can be formed on the first upper dielectric layer 2113.

As shown in FIG. 22, a PR mask 2270 can be patterned by photolithography, for example, and formed to cover a portion of the cap layer 2180 (and the stack), and the rest of the cap layer 2180 (and the stack) that is not covered by the PR mask 2270 can be etched downward until uncovering the top surface of the substrate 2100 to form at least one opening, e.g., first and second openings 2291 and 2292. The first and second openings 2291 and 2292 allow the first and second VFETs to be formed therein, respectively.

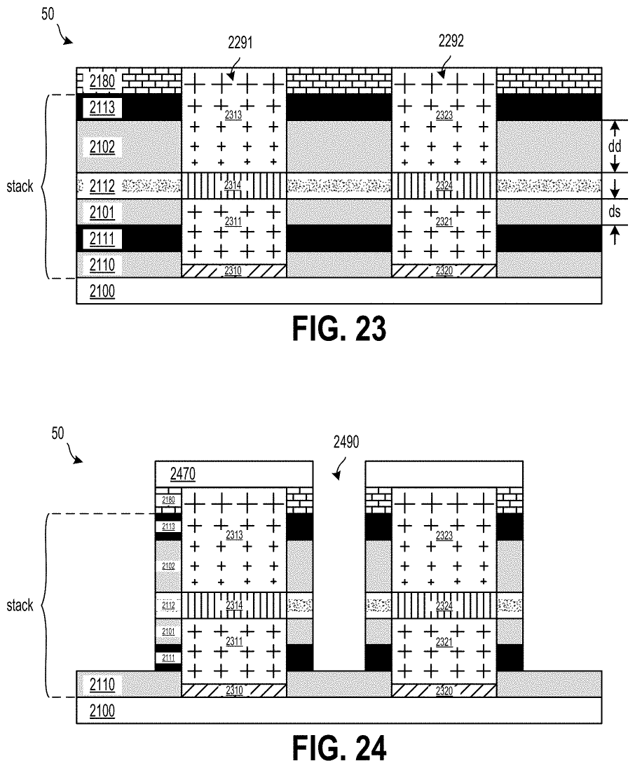

As shown in FIG. 23, the PR mask 2270 (which is shown in FIG. 22) can be removed, and first and second (sacrificial) epitaxial material 2310 and 2320 can be formed (e.g., epitaxially grown) on the substrate 2100 within the first and second openings 2291 and 2292, respectively. A first source region 2311 of the first VFET and a second source region 2321 of the second VFET can be formed (e.g., epitaxially grown) on the first and second epitaxial materials 2310 and 2320, respectively, with a lower channel material, e.g., a P type or N type epitaxial material, until being aligned with the second lower dielectric layer 2101. First and second epitaxial channels 2314 and 2324 can be formed on the first and second source regions 2311 and 2321, respectively, until being aligned with the middle dielectric layer 2112. A first drain region 2013 of the first VFET and a second drain region 2323 of the second VFET can be formed (e.g., epitaxially grown) on the first and second epitaxial channels 2314 and 2324, respectively, with a higher channel material, e.g., a P type or N type epitaxial material, until being aligned with the first upper dielectric layer 2113 or the cap layer 2180. The higher channel material can have a graded dopant profile. Accordingly, the first and second source regions 2311 and 2321 and the first and second drain regions 2313 and 2323 have asymmetrical dopant profiles.

As shown in FIG. 24, a PR mask 2470 can be patterned by photolithography, for example, and formed to cover a portion of the cap layer 2180 over the entire first and second drain regions 2313 and 2323 of the first and second VFETs, and the rest of the cap layer 2180 that is not covered by the PR mask 2470 can be etched downward until uncovering at least the top surface of the bottom dielectric layer 2110, to form an opening 2490.

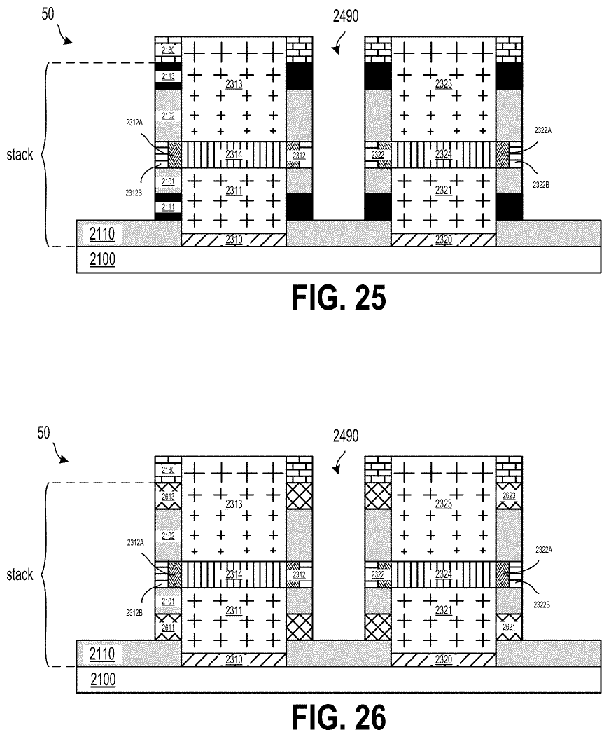

As shown in FIG. 25, the PR mask 2470 (which is shown in FIG. 24) can be removed, and the middle dielectric layer 2112 (which is shown in FIG. 24), which is etched selectively with respect to the first lower and upper dielectric layers 2111 and 2113, the second lower and upper dielectric layers 2101 and 2102 and the bottom dielectric layer 2110, can be etched and removed.

Also shown in FIG. 25, the removed middle dielectric layer 2112 (which is shown in FIG. 24) surrounding the first VFET can be replaced with a first gate material 2312A and a first metal material 2312B to form a first gate region 2312 of the first VFET, and the removed middle dielectric layer 2112 surrounding the second VFET can be replaced with a second gate material 2322A and a second metal material 2322B to form a second gate region 2322 of the second VFET. In an embodiment, the first gate material 2312A can include a first high-k material, and the second gate material 2322A can include a second high-k material that can be the same as or different from the first high-k material. In another embodiment, at least one of the first and second metal materials 2312B and 2322B can include two or more dielectric layered metal. The excess first and second metal materials 2312B and 2322B can be etched such that the first and second metal materials 2312B and 2322B can be aligned with the edge of the cap layer 2180.

As shown in FIG. 26, the first lower and upper dielectric layers 2111 and 2113 (which are shown in FIG. 25), which are etched selectively with respect to the second lower and upper dielectric layers 2101 and 2102 and the bottom dielectric layer 2110, can be etched and removed. The removed first lower and upper dielectric layers 2111 and 2113 surrounding the first VFET can be replaced with first S/D metal layers 2611 and 2613, respectively, and the removed first lower and upper dielectric layers 2111 and 2113 surrounding the second VFET can be replaced with second S/D metal layers 2621 and 2623, respectively.

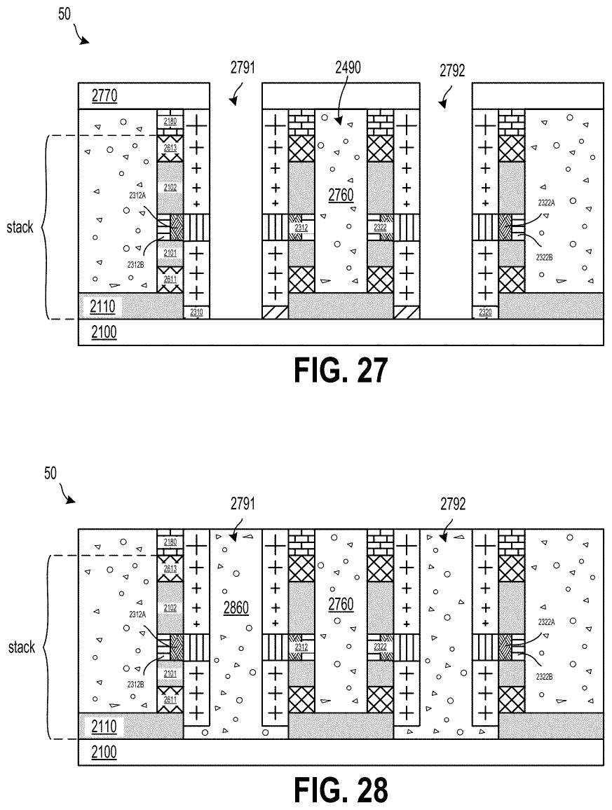

As shown in FIG. 27, a dielectric material 2760 can be deposited to fill the opening 2490 and planarized using CMP, for example, to be aligned with the cap layer 2180. A PR mask 2770 can be patterned by photolithography, for example, and formed to cover a portion of the cap layer 2180 (and the stack), and the rest of the cap layer 2180 (and the stack) that is not covered by the PR mask 2770 can be etched downward until uncovering the top surface of the substrate 2100 to form first and second openings 2791 and 2792.

As shown in FIG. 28, the PR mask 2770 (which is shown in FIG. 27) can be removed, and the first and second epitaxial materials 2310 and 2320 (which are shown in FIG. 27) can then be removed. A dielectric material 2860 can be deposited to fill the first and second openings 2791 and 2792 and planarized using CMP, for example, to be aligned with the cap layer 2180.

Accordingly, the semiconductor structure 50 can be formed to include the first and second VFETs, each of which has asymmetrical S/D dopant profiles and asymmetrical S/D spacers.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the disclosure. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the disclosure. Such variations are intended to be covered by the scope of this disclosure. As such, the foregoing descriptions of embodiments of the disclosure are not intended to be limiting. Rather, any limitations to embodiments of the disclosure are presented in the following claims.

What is claimed is:

1. A three-dimensional (3D) semiconductor structure, comprising:
a first vertical field-effect transistor (VFET) including a first lower source/drain (S/D) region, a first channel formed on the first lower S/D region, a first gate region surrounding the first channel, and a first upper S/D region formed on the first channel,
wherein one of the first lower and upper S/D regions includes a first channel material having a first graded dopant profile.

2. The 3D semiconductor structure of claim 1, wherein the first VFET further includes a first lower S/D electrode coupled to the first lower S/D region, a first gate electrode coupled to the first gate region, a first lower S/D spacer formed between the first lower S/D electrode and the first gate electrode, a first upper S/D electrode coupled to the first upper S/D region, and a first upper S/D spacer formed between the first gate electrode and the first upper S/D electrode, the first upper S/D spacer having a different thickness from the first lower S/D spacer.

3. The 3D semiconductor structure of claim 1, further comprising a second VFET stacked over the first VFET, the second VFET including a second lower S/D region formed over the first VFET, a second channel formed on the second lower S/D region, a second gate region surrounding the second channel, and a second upper S/D region formed on the second channel.

4. The 3D semiconductor structure of claim 3, wherein one of the second lower S/D region and the second upper S/D region includes a second channel material having a second graded dopant profile.

5. The 3D semiconductor structure of claim 3, wherein the first channel and the second channel include different types of channel materials.

6. The 3D semiconductor structure of claim 1, wherein the first gate region includes a first gate material coupled to the first channel and a first metal material coupled to the first gate material.

7. A 3D semiconductor structure, comprising:
a first VFET including a first S/D region, a first channel formed on the first lower S/D region, a first gate region surrounding the first channel, a first upper S/D region formed on the first channel, a first lower S/D electrode coupled to the first lower S/D region, a first gate electrode coupled to the first gate region, a first lower S/D spacer formed between the first lower S/D electrode and the first gate electrode, a first upper S/D electrode coupled to the first upper S/D region, and a first upper S/D spacer formed between the first gate electrode and the first upper S/D electrode,
wherein the first upper S/D spacer has a different thickness from the first lower S/D spacer.

8. The 3D semiconductor structure of claim 7, wherein one of the first lower S/D region and the first upper S/D region includes a first channel material having a first graded dopant profile.

9. A method for fabricating a 3D semiconductor structure, comprising:
forming a multilayer stack on a substrate;
forming a first opening through the multilayer stack until uncovering a top surface of the substrate;
forming in the first opening a first VFET that includes a first lower S/D region, a first channel formed on the first lower S/D region, and a first upper S/D region formed on the first channel; and
forming a first gate region of the first VFET surrounding the first channel,
wherein one of the first lower S/D region and the first upper S/D region includes a first channel material having a first graded dopant profile.

10. The method of claim 9, wherein the multilayer stack includes a first lower S/D layer and a first upper S/D layer coupled to the first lower S/D region and the first upper S/D region, respectively, a first gate layer coupled to the first gate region, a second lower S/D layer formed between the first lower S/D layer and the first gate layer, and a second upper S/D layer formed between the first upper S/D layer and the first gate layer, the second upper S/D layer having a different thickness from the second lower S/D layer.

11. The method of claim 10, wherein the first lower S/D layer and the first upper S/D layer include a first metal layer and a second metal layer, respectively.

12. The method of claim 10, wherein the first lower S/D layer and the first upper S/D layer include a first lower dielectric layer and a first upper dielectric layer, respectively, and the method further comprises:
replacing the first lower dielectric layer and the first upper dielectric layer with a first lower metal layer and a first upper metal layer, respectively.

13. The method of claim 9, further comprising:
forming in the first opening a second VFET over the first VFET, the second VFET including a second lower S/D region formed over the first VFET, a second channel formed on the second lower S/D region, and a second upper S/D region formed on the second channel; and
forming a second gate region of the second VFET surrounding the second channel.

14. The method of claim 13, wherein one of the second lower S/D region and the second upper S/D region includes a second channel material having a second graded dopant profile.

15. The method of claim 13, wherein the first channel and the second channel include different types of channel materials.

16. The method of claim 9, wherein the first gate region includes a first gate material coupled to the first channel and a first metal material coupled to the first gate material.

17. The method of claim 16, wherein the multilayer stack includes a dielectric layer coupled to the first channel, and the method further comprises:
replacing the dielectric layer with the first gate material and the first metal material to form the first gate region.

18. The method of claim 9, wherein the first gate region is formed in the first opening.

19. The method of claim 9, further comprising:
forming a second opening through the multilayer stack until uncovering the top surface of the substrate; and
forming in the second opening a second VFET.

20. The method of claim 19, wherein the second opening has a different size from the first opening.
